(19) United States
(12) Patent Application Publication
(10) Pub. No.: US 2025/0132277 A1
(43) Pub. Date: Apr. 24, 2025

(54) SEMICONDUCTOR PACKAGE

(71) Applicant: Samsung Electronics Co., Ltd., Suwon-si (KR)

(72) Inventors: Seokbeom Yong, Suwon-si (KR); Jaesun Kim, Suwon-si (KR)

(21) Appl. No.: 18/801,963

(22) Filed: Aug. 13, 2024

(30) Foreign Application Priority Data
Oct. 24, 2023 (KR) 10-2023-0143255

(51) Int. Cl. H01L 23/00; H01L 23/31; H01L 23/498; H01L 23/538; H01L 25/10

(52) U.S. Cl. CPC H01L 24/14; H01L 23/5385; H01L 24/16; H01L 25/105; H01L 23/3107; H01L 23/49811; H01L 2224/1403; H01L 2224/16237; H01L 2225/1058

(57) ABSTRACT

A semiconductor package includes a lower redistribution structure, a lower semiconductor chip on the lower redistribution structure, and an upper redistribution structure t on the lower semiconductor chip and including a signal pad, a power pad, a grounding plane, and an upper insulation layer, where the signal pad, the power pad, and the grounding plane are in the upper insulation layer, where a distance between the signal pad and the lower redistribution structure in a vertical direction is less than a distance between the power pad and the lower redistribution structure in the vertical direction, and where the vertical direction is perpendicular to an upper surface of the lower redistribution structure.

### CROSS-REFERENCE TO RELATED APPLICATION

This application is based on and claims priority under 35 U.S.C. § 119 to Korean Patent Application No. 10-2023-0143255, filed on Oct. 24, 2023, in the Korean Intellectual Property Office, the disclosure of which is incorporated by reference herein in its entirety.

### TECHNICAL FIELD

The present disclosure relates to a semiconductor package, and more particularly, to a package-on-package type semiconductor package.

### BACKGROUND

The storage capacity of semiconductor chips is increasing, and at the same time, semiconductor packages including semiconductor chips may be desired to be thin and light. Also, research is being conducted to include semiconductor chips of various functions in a semiconductor package and to quickly drive the semiconductor chips. In response to the trend, research associated with a package-on-package type semiconductor package having a structure in which an upper semiconductor package is mounted on a lower semiconductor package are being conducted.

### SUMMARY

The present disclosure provides a semiconductor package with improved input/output reliability of an upper redistribution structure.

The present disclosure provides a semiconductor package that suppresses the generation of parasitic capacitance in an upper redistribution structure.

In addition, the technical goals to be achieved by the present disclosure are not limited to the technical goals mentioned above, and other technical goals may be clearly understood by one of ordinary skill in the art from the following descriptions.

According to an aspect of the present disclosure, there is provided a semiconductor package including a lower redistribution structure, a lower semiconductor chip on the lower redistribution structure, and an upper redistribution structure on the lower semiconductor chip and including a signal pad, a power pad, a grounding plane, and an upper insulation layer, where the signal pad, the power pad, and the grounding plane are in the upper insulation layer, where a distance between the signal pad and the lower redistribution structure in a vertical direction is less than a distance between the power pad and the lower redistribution structure in the vertical direction, and where the vertical direction is perpendicular to an upper surface of the lower redistribution structure.

According to another aspect of the present disclosure, there is provided a semiconductor package including a lower redistribution structure, a lower semiconductor chip on the lower redistribution structure, and an upper redistribution structure on the lower semiconductor chip and including a signal redistribution pattern, a power pad, a grounding plane, and an upper insulation layer, where the upper redistribution structure includes a plurality of redistribution layers, where a first upper redistribution layer of the plurality of redistribution layers includes a first region and a second region, where the grounding plane is in the first region, and where a signal pad of the signal redistribution pattern is on the second region.

According to another aspect of the present disclosure, there is provided a semiconductor package including a lower redistribution structure, a lower semiconductor chip on the lower redistribution structure, a molding layer on the lower redistribution structure and at least partially surrounding the lower semiconductor chip, an upper redistribution structure on the molding layer and including a signal pad, a power pad, a grounding plane, and an upper insulation layer, a via electrode extending into the molding layer and electrically connects the lower redistribution structure to the upper redistribution structure, and an upper semiconductor chip on the upper redistribution structure, where the signal pad, the power pad, and the grounding plane are in the upper insulation layer, where a distance between the signal pad and the lower redistribution structure in a vertical direction is identical to a distance between the grounding plane and the lower redistribution structure in the vertical direction, and where the vertical direction is perpendicular to an upper surface of the lower redistribution structure.

### BRIEF DESCRIPTION OF THE DRAWINGS

Embodiments of the present disclosure will be more clearly understood from the following detailed description taken in conjunction with the accompanying drawings in which:

FIG. 1 is a schematic cross-sectional view of a semiconductor package according to some embodiments;

FIG. 2 is an enlarged view of a portion of the semiconductor package of FIG. 1;

FIG. 3 is a schematic plan view of a portion “EX1” of the semiconductor package of FIG. 2;

FIG. 4 is a schematic cross-sectional view of a semiconductor package according to some embodiments;

FIG. 5 is an enlarged view of a portion of the semiconductor package of FIG. 4;

FIG. 6 is a schematic cross-sectional view of a semiconductor package according to some embodiments;

FIG. 7 is an enlarged view of a portion of the semiconductor package of FIG. 6;

FIG. 8 is a schematic plan view of a portion “EX2” of the semiconductor package of FIG. 7;

FIG. 9 is a schematic cross-sectional view of a semiconductor package according to some embodiments;

FIG. 10 is an enlarged view of a portion of the semiconductor package of FIG. 9;

FIG. 11 is a schematic cross-sectional view of a semiconductor package according to some embodiments; and

FIG. 12 is a schematic cross-sectional view of a semiconductor package according to some embodiments.

### DETAILED DESCRIPTION OF THE EMBODIMENTS

To clarify the present disclosure, parts that are not connected with the description will be omitted, and the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and case of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements and/or components, but do not preclude the presence or addition of one or more other features, steps, operations, elements, components and/or groups thereof. The term “and/or” includes any and all combinations of one or more of the associated listed items. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction. The term “exposed” may be used to define a relationship between particular layers or surfaces, but it does not require the layer or surface to be free of other elements or layers thereon in the completed device.

Hereinafter, embodiments will be described in detail with reference to accompanying drawings. In the drawings, like reference numerals are used for like elements and redundant descriptions thereof will be omitted.

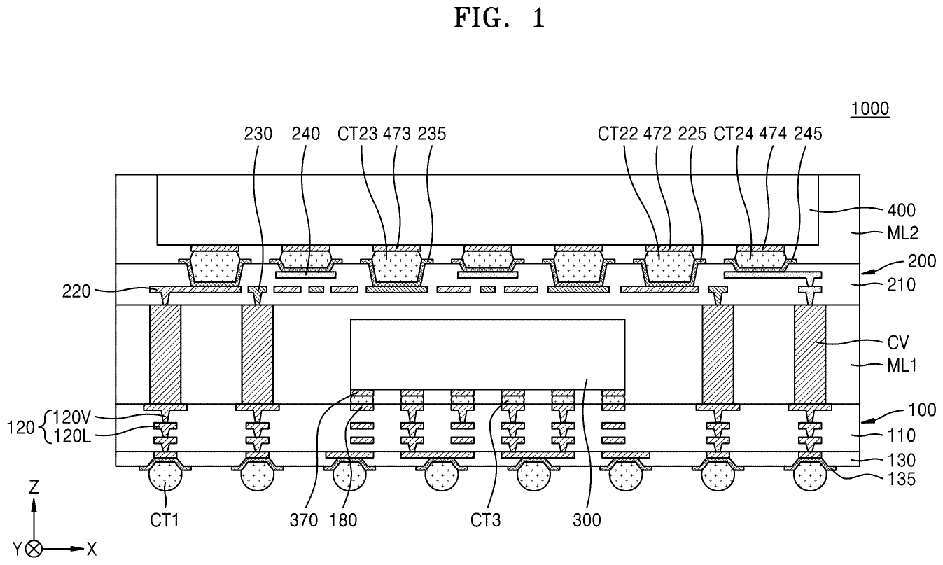

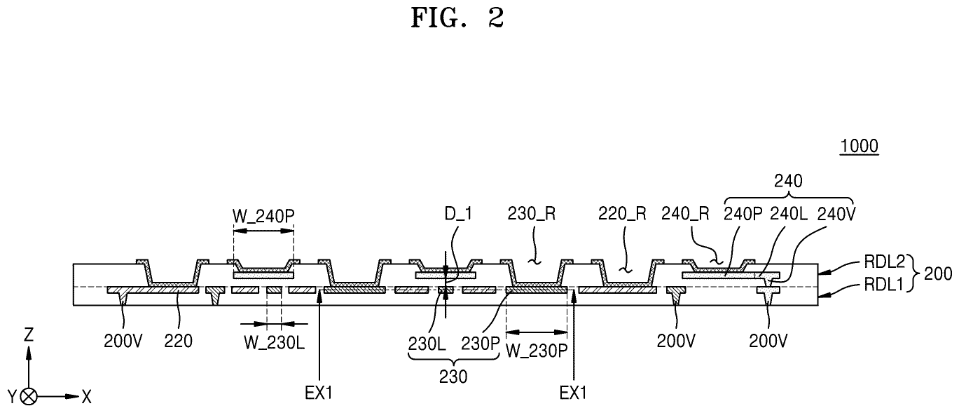

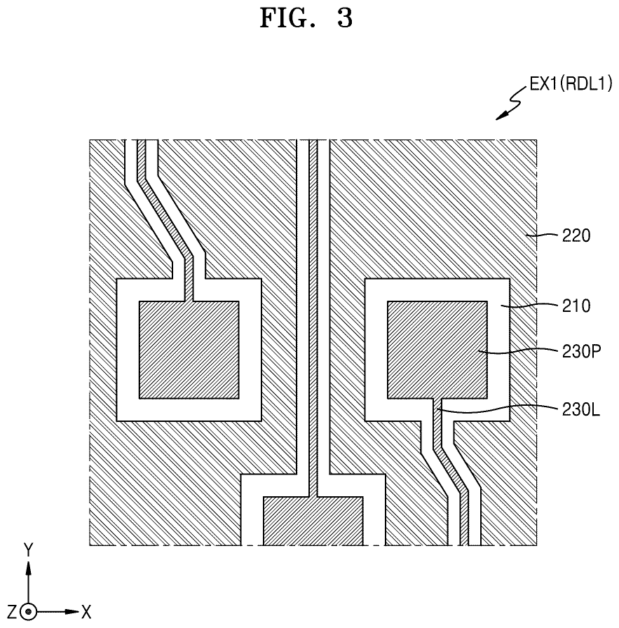

FIG. 1 is a schematic cross-sectional view of a semiconductor package 1000 according to some embodiments. FIG. 2 is an enlarged view of a portion of the semiconductor package 1000 of FIG. 1. FIG. 3 is a schematic plan view of a portion “EX1” of the semiconductor package 1000 of FIG. 2.

The semiconductor package 1000 may include a lower redistribution structure 100, a lower semiconductor chip 300, an upper redistribution structure 200, and an upper semiconductor chip 400. According to some embodiments, the semiconductor package 1000 may further include a first molding layer ML1, a second molding layer ML2, and a via electrode CV.

Hereinafter, unless specifically defined, the direction parallel to the top surface of the lower redistribution structure 100 is defined as a first direction (X direction), the direction perpendicular to the top surface of the lower redistribution structure 100 is defined as a vertical direction (Z direction), and the direction perpendicular to the first direction (X direction) and the vertical direction (Z direction) is defined as a second direction (Y direction). The first direction (X direction) and the second direction (Y direction) are collectively defined as a horizontal direction or horizontal directions.

The lower redistribution structure 100 of the semiconductor package 1000 may extend input/output terminals of the lower semiconductor chip 300 to an outer region of the lower semiconductor chip 300. The lower redistribution structure 100 may include a lower insulation layer 110 and a lower redistribution pattern 120 including a lower via pattern 120V and a lower line pattern 120L.

The numbers and the arrangements of the lower via pattern 120V and the lower line pattern 120L are not limited to those shown in the drawings and may vary according to embodiments.

The lower insulation layer 110 may include an insulation material, e.g., photo imageable dielectric (PID) resin. In this case, the lower insulation layer 110 may further include an inorganic filler. According to some embodiments, the lower insulation layer 110 may have a multi-layered structure in which a lower redistribution pattern is disposed on each layer.

The lower redistribution pattern 120 may expand the input/output terminal of the lower semiconductor chip 300 to the outside. The lower line pattern 120L may be disposed on at least one of the top surface and the bottom surface of the lower insulation layer 110 or inside the lower insulation layer 110. The lower via pattern 120V may penetrate or extend into the lower insulation layer 110 and be connected to a portion of the lower line pattern 120L.

The lower via pattern 120V may be completely filled with or include a conductive material or may have a shape in which a conductive material is formed along the wall of a via. The lower redistribution pattern 120 may include a conductive material, e.g., Cu, aluminum (Al), silver (Ag), tin (Sn), gold (Au), nickel (Ni), lead (Pb), titanium (Ti), or alloys thereof.

According to some embodiments, the semiconductor package 1000 may further include a lower passivation layer 130. The lower passivation layer 130 is disposed on the bottom surface of the lower redistribution structure 100 and may protect the lower redistribution structure 100. The lower passivation layer 130 may include an insulation material, e.g., thermosetting resin or thermoplastic resin, but is not limited thereto.

For example, at least a portion of the lower line pattern 120L may be exposed through openings of the lower passivation layer 130. The exposed portion of the lower line pattern 120L may be electrically connected to lower metal layers 135 disposed inside or in the openings of the passivation layer 130. External connection terminals CT1 may be electrically connected to the lower metal layers 135, respectively.

The external connection terminals CT1 may connect the semiconductor package 1000 to a main board of a separate electronic device on which the semiconductor package 1000 is mounted. The external connection terminals CT1 may include a conductive material, e.g., at least one of solder, Sn, Ag, Cu, and Al. The external connection terminals CT1 may have various shapes, such as a land-like shape, a bump-like shape, a pillar-like shape, a pin-like shape, or a ball-like shape.

The lower semiconductor chip 300 of the semiconductor package 1000 may include an active surface and an inactive surface opposite thereto. The lower semiconductor chip 300 may be disposed on the lower redistribution structure 100 such that the active surface of the lower semiconductor chip 300 faces the lower redistribution structure 100. For example, the lower semiconductor chip 300 may be disposed on the lower redistribution structure 100 in a face-down manner.

The lower semiconductor chip 300 may include, for example, a semiconductor material, such as silicon (Si) or germanium (Ge). Alternatively, the lower semiconductor chip 300 may include a compound semiconductor material, such as silicon carbide (SiC), gallium arsenide (GaAs), indium arsenide (InAs), and indium phosphide (InP). The lower semiconductor chip 300 may include a well doped with an impurity, which is a conductive region. Also, the lower semiconductor chip 300 may have various device isolation structures, such as a shallow trench isolation (STI) structure.

A semiconductor device including a plurality of individual devices of various types may be formed on the active surface of the lower semiconductor chip 300. The plurality of individual devices may be electrically connected to a conductive region of the lower semiconductor chip 300.

The semiconductor device may further include conductive wires or conductive plugs electrically connecting the plurality of individual devices to the conductive region of the lower semiconductor chip 300. Also, the individual devices may each be electrically separated or insulated from other neighboring individual devices by an insulation film.

According to some embodiments, the lower semiconductor chip 300 may include a logic device. For example, the lower semiconductor chip 300 may be a central processing unit chip, a graphics processing unit chip, or an application processor (AP). According to other embodiments, when a semiconductor package includes a plurality of lower semiconductor chips 300, one of the plurality of lower semiconductor chips 300 may be a central processing unit chip, a graphics processing unit chip, or an AP chip, and another one of the plurality of lower semiconductor chips 300 may be a memory semiconductor chip including a memory device.

For example, the memory device may be a non-volatile memory device, such as flash memory, phase-change random access memory (PRAM), magnetic random access memory (MRAM), ferroelectric random access memory (FeRAM), or resistive random access memory (RRAM). According to some embodiments, the memory device may be a volatile memory device, such as dynamic random access memory (DRAM) or static random access memory (SRAM).

According to some embodiments, the lower semiconductor chip 300 may further include an input/output pad 370. The input/output pad 370 may be electrically connected to the conductive region of the lower semiconductor chip 300. For example, the input/output pad 370 may include a conductive material, e.g., aluminum (Al).

The input/output pad 370 of the lower semiconductor chip 300 may be electrically connected to an upper pad 180 of the lower redistribution structure 100 through a connection terminal CT3. For example, the lower semiconductor chip 300 may be mounted on the lower redistribution structure 100 through a chip-last process.

According to some embodiments, the lower via pattern 120V of the lower redistribution structure 100 may have a tapered shape in which the horizontal width of the lower via pattern 120V decreases as the distance from the lower semiconductor chip 300 increases.

The first molding layer ML1 of the semiconductor package 1000 may be located on the lower redistribution structure 100 and may at least partially surround the lower semiconductor chip 300. According to some embodiments, the first molding layer ML1 may include epoxy resin or polyimide resin. The first molding layer ML1 may include, for example, epoxy molding compound (EMC).

According to some embodiments, the first molding layer ML1 may cover or overlap the top surface of the lower semiconductor chip 300. For example, the first molding layer ML1 may be located between the lower semiconductor chip 300 and the upper redistribution structure 200.

According to some embodiments, the horizontal width of the first molding layer ML1 may be substantially equal to the horizontal width of each of the lower redistribution structure 100 and the upper redistribution structure 200. For example, side surfaces of the first molding layer ML1, side surfaces of the lower redistribution structure 100, and side surfaces of the upper redistribution structure 200 may be substantially coplanar with one another.

The via electrode CV of the semiconductor package 1000 may penetrate or extend into the first molding layer ML1. The via electrode CV may penetrate or extend into the first molding layer ML1 and electrically connect the lower redistribution structure 100 and the upper redistribution structure 200. For example, the via electrode CV may include a conductive material, e.g., Cu, aluminum (Al), silver (Ag), tin (Sn), gold (Au), nickel (Ni), lead (Pb), titanium (Ti), or alloys thereof.

Referring to FIGS. 2 and 3, the upper redistribution structure 200 will be described.

The upper redistribution structure 200 of the semiconductor package 1000 may be located above the lower semiconductor chip 300. For example, the upper redistribution structure 200 may be located on the first molding layer ML1.

The upper redistribution structure 200 may include an upper redistribution pattern and an upper insulation layer 210 at least partially surrounding the upper redistribution pattern. The upper redistribution pattern of the upper redistribution structure 200 may be electrically connected to the via electrode CV through an upper via 200V.

The upper redistribution pattern may include a grounding plane 220, a signal redistribution pattern 230, and a power redistribution pattern 240. The grounding plane 220, the signal redistribution pattern 230, and the power redistribution pattern 240 may be located inside or in the upper insulation layer 210.

The upper redistribution structure 200 may have a multi-layered structure including the upper insulation layer 210 having at least two layers. An upper redistribution pattern may be located on each layer of the upper insulation layer 210.

The upper insulation layer 210 may include a PID resin. In this case, the upper insulation layer 210 may further include an inorganic filler.

The signal redistribution pattern 230 may include a signal line pattern 230L and a signal pad 230P. The signal line pattern 230L extends in the horizontal direction, and the signal pad 230P may be electrically connected to the signal line pattern 230L. The signal pad 230P may be a region of the signal redistribution pattern 230 exposed to the outside through a second groove 230_R.

The signal line pattern 230L and the signal pad 230P may have the same vertical level. In other words, the signal line pattern 230L and the signal pad 230P may be located on the same layer of the upper insulation layer 210.

In this specification, the “vertical level of element A” refers to a vertical distance (e.g., a distance in the Z direction) between element A and the bottom or upper surface of the lower redistribution structure 100. In this specification, the “element A and element B are located at (or have) the same vertical level” refers to element A and element B having a same vertical distance between the respective element and the bottom or upper surface of the lower redistribution structure 100. In this specification, the “element A is located at (or has) a lower vertical level than element B” refers to element A having a first vertical distance between the respective element and the bottom or upper surface of the lower redistribution structure 100, and element B having a second vertical distance between the respective element and the bottom or upper surface of the lower redistribution structure 100, where the first vertical distance is less than the second vertical distance. In this specification, the “element A is located at (or has) a higher vertical level than element B” refers to element A having a first vertical distance between the respective element and the bottom or upper surface of the lower redistribution structure 100, and element B having a second vertical distance between the respective element and the bottom or upper surface of the lower redistribution structure 100, where the first vertical distance is greater than the second vertical distance.

According to some embodiments, a horizontal width W_230P of the signal pad 230P may be from about 10 times to about 30 times greater than a horizontal width W_230L of the signal line pattern 230L. For example, the horizontal width W_230L of the signal line pattern 230L may be from about 10 μm to about 20 μm, and the horizontal width W_230P of the signal pad 230P may be from about 100 μm to about 300 μm. In this specification, the “horizontal width” refers to a length in a direction perpendicular to the direction in which the signal line pattern 230L extends.

The power redistribution pattern 240 may include a power plane 240L, a power pad 240P, and a power via pattern 240V. The power plane 240L is located on an arbitrary layer of the upper insulation layer 210 and may cover or overlap a portion of one surface of the arbitrary layer of the upper insulation layer 210. The power via pattern 240V penetrates or extends into the upper insulation layer 210 and may electrically connect the power plane 240L to the upper via 200V. According to some embodiments, the power plane 240L may be located on the uppermost layer of the upper insulation layer 210 and may be spaced apart from a first groove 220_R and the second groove 230_R in the horizontal direction. The power pad 240P may be a portion of the power plane 240L and be a region exposed to the outside through a third groove 240_R. According to some embodiments, when the power plane 240L constitutes a line pattern on the one surface of the arbitrary l″yer ′f the upper insulation layer 210, the power plane 240L may be referred to as a power line pattern.

According to some embodiments, as shown in FIG. 3, the grounding plane 220 may cover or overlap a region that does not include the signal redistribution pattern 230 and the power redistribution pattern 240 in any layer of the upper redistribution structure 200.

For example, the grounding plane 220 may be located on any layer of the upper redistribution structure 200. The grounding plane 220 is spaced apart in the horizontal direction from the signal redistribution pattern 230 and the power redistribution pattern 240 located on the arbitrary layer of the upper redistribution layer 200 and may cover or overlap the top surface of the lowest layer of the upper redistribution layer 200. The grounding plane 220 may be spaced apart from the signal line pattern 230L and the signal pad 230P in the horizontal direction, with the upper insulation layer 210 therebetween.

A portion of the grounding plane 220 may be exposed to the outside through the first groove 220_R. For example, the portion of the grounding plane 220 may be referred to as a grounding pad.

The vertical level of the signal pad 230P may be lower than the vertical level of the power pad 240P. In other words, the signal pad 230P may be located on a layer of the upper insulation layer 210 lower than the layer of the upper insulation layer 210 on which the power pad is located.

The vertical level of the signal pad 230P may be identical to the vertical level of the grounding plane 220. The signal pad 230P may be located on the layer of the upper insulation layer 210 on which the grounding plane 220 is located.

According to some embodiments, the signal pad 230P may be closer to the bottom surface of the upper insulation layer 210 than to the top surface of the upper insulation layer 210, and the power pad 240P may be closer to the top surface of the upper insulation layer 210 than to the bottom surface of the upper insulation layer 210. For example, the signal pad 230P may be spaced apart from the bottom surface of the upper insulation layer 210 by about 10 μm to about 50 μm, and the power pad 240P may be spaced apart from the top surface of the upper insulation layer 210 by about 10 μm to about 50 μm.

According to some embodiments, a separation distance D_1 between the signal pad 230P and the power pad 240P in the vertical direction (Z direction) may be from about 10 μm to about 50 μm. For example, the upper insulation layer 210 may be located in a space where the signal pad 230P and the power pad 240P are spaced apart.

According to some embodiments, the upper redistribution structure 200 may include the first groove 220_R, the second groove 230_R, and the third groove 240_R. The first groove 220_R may extend from the top surface of the upper insulation layer 210 toward the grounding plane 220, the second groove 230_R may extend from the top surface of the upper insulation layer 210 toward the signal pad 230P, and the third groove 240_R may extend from the top surface of the upper insulation layer 210 toward the power pad 240P.

A portion of the grounding plane 220 may be exposed to the outside through the first groove 220_R, the signal pad 230P may be exposed to the outside through the second groove 230_R, and the power pad 240P may be exposed to the outside through the third groove 240_R. The extending depth of the first groove 220_R may be equal to the separation distance between the grounding plane 220 and the top surface of the upper insulation layer 210, the extending depth of the second groove 230_R may be equal to the separation distance between the signal pad 230P and the top surface of the upper insulation layer 210, and the extending depth of the third groove 240_R may be equal to the separation distance between the power pad 240P and the top surface of the upper insulation layer 210.

According to some embodiments, the extending depth of the third groove 240_R may be less than the extending depth of the first groove 220_R and the extending depth of the second groove 230_R. The separation distance between the power pad 240P and the top surface of the upper insulation layer 210 may be less than the separation distance between the grounding plane 220 and the top surface of the upper insulation layer 210 and the separation distance between the signal pad 230P and the top surface of the upper insulation layer 210.

According to some embodiments, the extending depth of the first groove 220_R and the extending depth of the second groove 230_R may be substantially the same. The distance between the grounding plane 220 and the top surface of the upper insulation layer 210 may be substantially equal to the separation distance between the signal pad 230P and the top surface of the upper insulation layer 210.

According to some embodiments, the semiconductor package 1000 may further include a first metal layer 225 conformally located inside or in the first groove 220_R, a second metal layer 235 conformally located inside or in the second groove 230_R, and a third metal layer 245 conformally located inside or in the third groove 240_R. The first metal layer 225, the second metal layer 235, and the third metal layer 245 may protect a region of the upper redistribution pattern exposed to the outside.

For example, the upper redistribution structure 200 may include a first upper redistribution layer RDL1 and a second upper redistribution layer RDL2.

The first upper redistribution layer RDL1 may be in direct contact with the first molding layer ML1 and the via electrode CV, and the second upper redistribution layer RDL2 may be located on the first upper redistribution layer RDL1. For example, the first upper redistribution layer RDL1 may be referred to as the lowermost layer of the upper redistribution structure 200, and the second upper redistribution layer RDL2 may be referred to as the uppermost layer of the upper redistribution structure 200.

According to some embodiments, the signal redistribution pattern 230 and the grounding plane 220 may be located on the first upper redistribution layer RDL1, and the power redistribution pattern 240 may be located on the second upper redistribution layer RDL2. The signal pad 230P and the grounding plane 220 may be located on a layer lower than that of the power pad 240P, and the signal pad 230P and the grounding plane 220 may be located on the same layer.

The upper semiconductor chip 400 of the semiconductor package 1000 may be located on the upper redistribution structure 200. The upper semiconductor chip 400 may include an active surface and an inactive surface opposite thereto. The upper semiconductor chip 400 may be disposed on the upper redistribution structure 200 such that the active surface of the upper semiconductor chip 400 faces the upper redistribution structure 200. For example, the upper semiconductor chip 400 may be disposed on the upper redistribution structure 200 in a face-down manner.

The upper semiconductor chip 400 may include, for example, a semiconductor material, such as silicon (Si) or germanium (Ge). Alternatively, the upper semiconductor chip 400 may include a compound semiconductor material, such as silicon carbide (SiC), gallium arsenide (GaAs), indium arsenide (InAs), and indium phosphide (InP). The upper semiconductor chip 400 may include a well doped with an impurity, which is a conductive region. Also, the upper semiconductor chip 400 may have various device isolation structures, such as a STI structure.

A semiconductor device including a plurality of individual devices of various types may be formed on the active surface of the upper semiconductor chip 400. The plurality of individual devices may be electrically connected to a conductive region of the upper semiconductor chip 400.

The semiconductor device may further include conductive wires or conductive plugs electrically connecting the plurality of individual devices to the conductive region of the upper semiconductor chip 400. Also, the individual devices may each be electrically separated or insulated from other neighboring individual devices by an insulation film.

According to some embodiments, the upper semiconductor chip 400 may include a logic device. For example, the upper semiconductor chip 400 may be a central processing unit chip, a graphics processing unit chip, or an AP. According to other embodiments, when a semiconductor package includes a plurality of upper semiconductor chips 400, one of the plurality of upper semiconductor chips 400 may be a central processing unit chip, a graphics processing unit chip, or an AP chip, and another one of the plurality of upper semiconductor chips 400 may be a memory semiconductor chip including a memory device.

For example, the memory device may be a non-volatile memory device, such as flash memory, PRAM, MRAM, FeRAM, or RRAM. According to some embodiments, the memory device may be a volatile memory device, such as DRAM or SRAM.

The second molding layer ML2 of the semiconductor package 1000 may be located on the upper redistribution structure 200 and may at least partially surround the upper semiconductor chip 400. According to some embodiments, the second molding layer ML2 may include epoxy resin or polyimide resin. The second molding layer ML2 may include, for example, EMC.

According to some embodiments, the upper semiconductor chip 400 may further include a plurality of input/output pads. The plurality of input/output pads may be electrically connected to the conductive region of the upper semiconductor chip 400. For example, the plurality of input/output pads may include a conductive material, e.g., aluminum (Al).

A plurality of connection terminals may be located between the upper semiconductor chip 400 and the upper redistribution structure 200. The plurality of connection terminals may each penetrate or extend into a portion of the upper insulation layer 210 and contact the upper redistribution pattern. For example, the plurality of connection terminals may each be located inside or in a groove of the upper redistribution structure 200.

The plurality of input/output terminals of the upper semiconductor chip 400 may be electrically connected to the upper redistribution structure 200 through the plurality of connection terminals.

The plurality of input/output pads may include a first pad 472, a second pad 473, and a third pad 474. The plurality of connection terminals may include a first connection terminal CT22, a second connection terminal CT23, and a third connection terminal CT24. The first pad 472 may be electrically connected to the grounding plane 220 through the first connection terminal CT22, the second pad 473 may be electrically connected to the signal pad 230P through the second connection terminal CT23, and the third pad 474 may be electrically connected to the power pad 240P through the third connection terminal CT24.

The first connection terminal CT22 may be located in the first groove 220_R, the second connection terminal CT23 may be located in the second groove 230_R, and the third connection terminal CT24 may be located in the third groove 240_R. Therefore, the heights of the first connection terminal CT22, the second connection terminal CT23, and the third connection terminal CT24 may correspond to the extending depths of the first groove 220_R, the second groove 230_R, and the third groove 240_R, respectively.

In other words, the height of the first connection terminal CT22 may be substantially equal to the separation distance between the first pad 472 and the grounding plane 220 in the vertical direction (Z direction), the height of the second connection terminal CT23 may be substantially equal to the separation distance between the second pad 473 and the signal pad 230P in the vertical direction (Z direction), and the height of the third connection terminal CT24 may be substantially equal to the separation distance between the third pad 474 and the power pad 240P in the vertical direction (Z direction).

According to some embodiments, the height of the third connection terminal CT24 may be less than the height of each of the first connection terminal CT22 and the second connection terminal CT23. According to some embodiments, the height of the first connection terminal CT22 may be equal to the height of the third connection terminal CT24.

In the semiconductor package 1000, the signal pad 230P and the grounding plane 220 have the same vertical level, and thus the occurrence of a parasitic capacitance between the signal pad 230P and the grounding plane 220 may be suppressed. Therefore, the reliability of signals input/output to/from the upper semiconductor chip 400 may be improved.

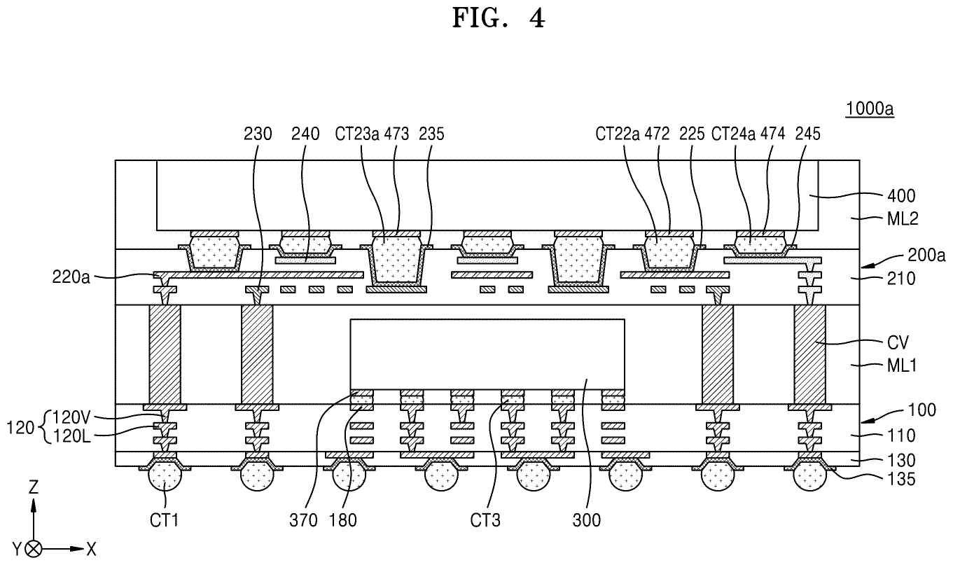

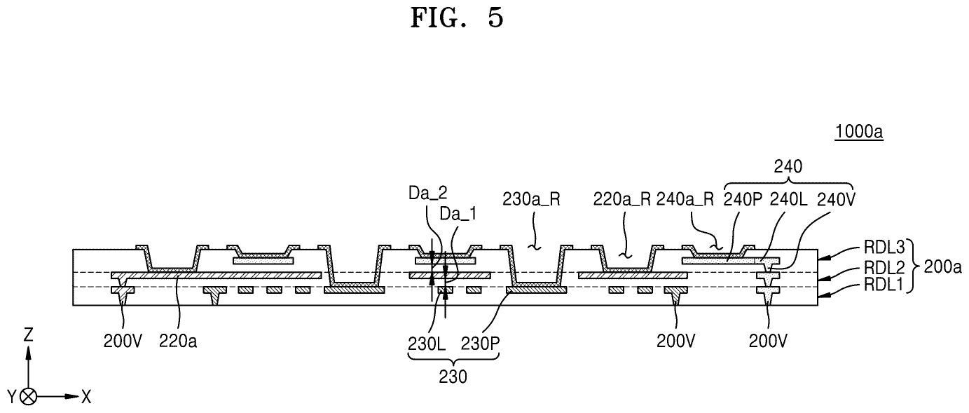

FIG. 4 is a schematic cross-sectional view of a semiconductor package 1000a according to some embodiments. FIG. 5 is an enlarged view of a portion of the semiconductor package 1000a of FIG. 4.

Most of the components constituting a semiconductor package 1000a described below and materials constituting the components thereof are substantially the same as or similar to those described with reference to FIG. 1 above. Therefore, for convenience of explanation, descriptions below focus on the differences between the semiconductor package 1000a of FIG. 4 and the semiconductor package 1000 of FIG. 1 described above.

An upper redistribution structure 200a of the semiconductor package 1000a may include the signal redistribution pattern 230, the power redistribution pattern 240, a grounding plane 220a, and the upper insulation layer 210.

The vertical level of the signal pad 230P may be lower than the vertical level of the grounding plane 220a. The vertical level of the grounding plane 220a may be lower than the vertical level of the power pad 240P.

According to some embodiments, the separation distance between the signal pad 230P and the top surface of the upper insulation layer 210 may be greater than the separation distance between the grounding plane 220a and the top surface of the upper insulation layer 210. The separation distance between the grounding plane 220a and the top surface of the upper insulation layer 210 may be greater than the separation distance between the power pad 240P and the top surface of the upper insulation layer 210.

According to some embodiments, the extending depth of a first groove 220a_R may be less than the extending depth of a second groove 230a_R, and the extending depth of the first groove 220a_R may be greater than the extending depth of a third groove 240a_R. According to some embodiments, the height of a first connection terminal CT22a may be less than the height of a second connection terminal CT23a. The height of the first connection terminal CT22a may be greater than the height of a third connection terminal CT24a.

The upper redistribution structure 200a may include the first upper redistribution layer RDL1, the second upper redistribution layer RDL2, and a third upper redistribution layer RDL3.

The first upper redistribution layer RDL1 may be in direct contact with the first molding layer ML1 and the via electrode CV, the second upper redistribution layer RDL2 may be located on the first upper redistribution layer RDL1, and the third upper redistribution layer RDL3 may be located on the second upper redistribution layer RDL2. For example, the first upper redistribution layer RDL1 may be referred to as the lowermost layer of the upper redistribution structure 200, and the third upper redistribution layer RDL3 may be referred to as the uppermost layer of the upper redistribution structure 200.

According to some embodiments, the signal redistribution pattern 230 may be located on the first upper redistribution layer RDL1, the grounding plane 220 may be located on the second upper redistribution layer RDL2, and the power redistribution pattern 240 may be located on the third upper redistribution layer RDL3. For example, a separation distance Da_1 between the signal redistribution pattern 230 and the grounding plane 220a may be from about 10 μm to about 50 μm, and a separation distance Da_2 between the grounding plane 220a and the power pad 240P may be from about 10 μm to about 50 μm.

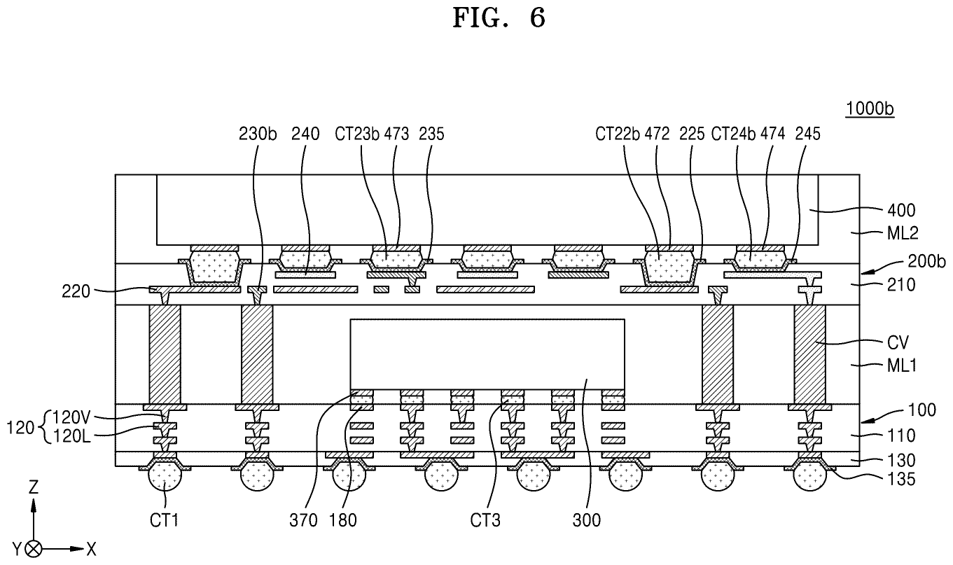

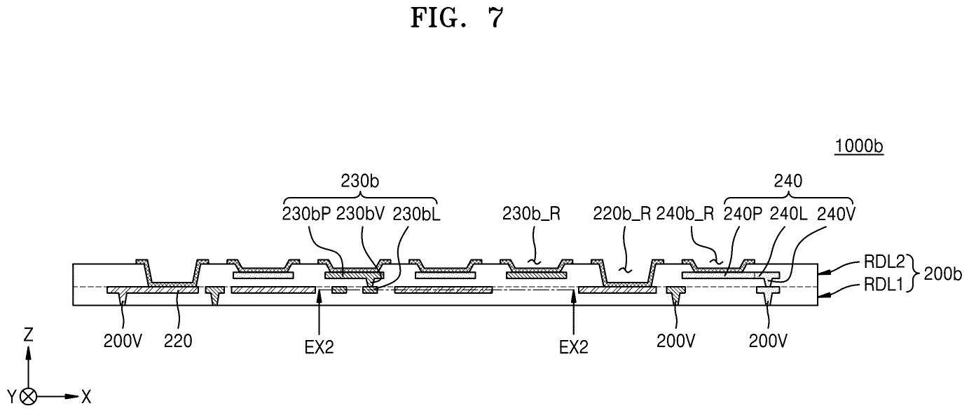

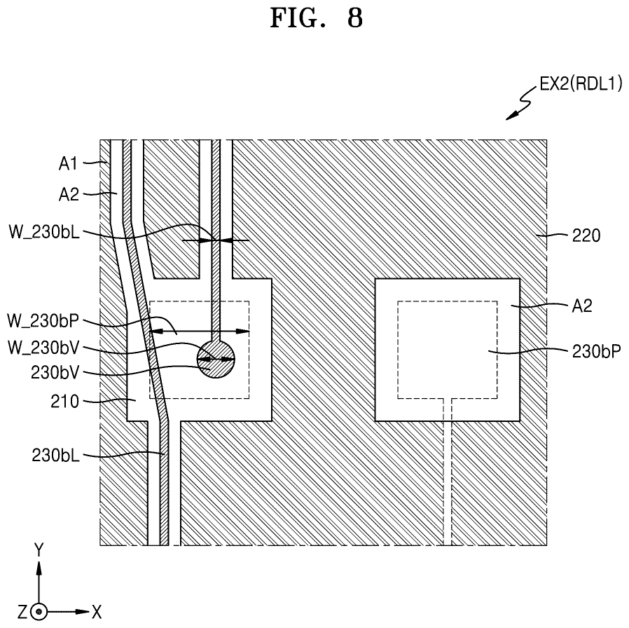

FIG. 6 is a schematic cross-sectional view of a semiconductor package 1000b according to some embodiments. FIG. 7 is an enlarged view of a portion of the semiconductor package 1000b of FIG. 6. FIG. 8 is a schematic plan view of a portion “EX2” of the semiconductor package 1000b of FIG. 7.

In detail, FIG. 8 is a plan view of a portion of the first upper redistribution layer RDL1 in which the grounding plane 220 and a signal redistribution pattern 230b are located. The locations of a signal pad 230bP and the signal pad 230bP located on the second upper redistribution layer RDL2 are indicated by a dashed line in FIG. 8.

Most of the components constituting a semiconductor package 1000b described below and materials constituting the components thereof are substantially the same as or similar to those described with reference to FIG. 1 above. Therefore, for convenience of explanation, descriptions below focus on the differences between the semiconductor package 1000b of FIG. 6 and the semiconductor package 1000 of FIG. 1 described above.

An upper redistribution structure 200b of the semiconductor package 1000b may include the signal redistribution pattern 230b, the power redistribution pattern 240, the grounding plane 220, and the upper insulation layer 210.

The upper redistribution structure 200b may have a multi-layered structure. For example, the upper redistribution structure 200b may have a structure in which the plurality of upper insulation layers 210 including an upper redistribution pattern are stacked. The grounding plane 220 may be located on the first upper redistribution layer RDL1 of the upper redistribution structure 200b.

The first upper redistribution layer RDL1 where the grounding plane 220 is located may be divided into a first region A1 and a second region A2. The first region A1 is a region where the grounding plane 220 is located, and the second region A2 may be the remaining region. For example, a portion of the upper insulation layer 210, a signal line pattern 230bL, and a signal via pattern 230bV may be located in the second region A2.

The signal redistribution pattern 230b may include the signal pad 230bP, the signal line pattern 230bL, and the signal via pattern 230bV. For example, the signal line pattern 230bL may have a vertical level lower than that of the signal pad 230bP. In other words, the signal line pattern 230bL and the signal pad 230bP may be located on different layers. The signal via pattern 230bV may electrically connect the signal line pattern 230bL to the signal pad 230bP.

A horizontal width W_230bP of the signal pad 230bP may be greater than a horizontal width W_230bV of the signal via pattern 230bV, and the horizontal width W_230bV of the signal via pattern 230bV may be greater than a horizontal width W_230bL of the signal line pattern 230bL. For example, the horizontal width W_230bP of the signal pad 230bP may be from about 100 μm to about 300 μm, the horizontal width W_230bV of the signal via pattern 230bV may be from about 20 μm to about 50 μm, and the horizontal width W_230bL of the signal line pattern 230bL may be from about 10 μm to about 20 μm.

According to some embodiments, the signal line pattern 230bL may have the same vertical level as the signal pad 230bP and may further include a joint line pattern extending from the signal pad 230bP in the horizontal direction. The signal via pattern 230bV may be located on the bottom surface of the joint line pattern. In other words, the signal pad 230bP and the signal via pattern 230bV may not overlap each other in the vertical direction.

However, the present disclosure is not limited thereto. The signal via pattern 230bV may be located on the bottom surface of the signal pad 230bP, and the signal pad 230bP may overlap the signal via pattern 230bV and the signal line pattern 230bL in the vertical direction (Z direction).

According to some embodiments, the signal pad 230bP may be located on the second region A2. In other words, the signal pad 230bP may not overlap the grounding plane 220 in the vertical direction (Z direction). Since the grounding plane 220 is not located below the signal pad 230bP, the occurrence of a parasitic capacitance between the signal pad 230bP and the grounding plane 220 may be suppressed.

According to some embodiments, the vertical level of the signal line pattern 230bL may be identical to the vertical level of the grounding plane 220. In other words, the signal line pattern 230bL may be located above or on the first upper redistribution layer RDL1 where the grounding plane 220 is located.

According to some embodiments, the vertical level of the signal pad 230bP and the vertical level of the power pad 240P may be higher than the vertical level of the grounding plane 220. For example, the power pad 240P may overlap the grounding plane 220 in the vertical direction (Z direction), and the signal pad 230bP may not overlap the grounding plane 220 in the vertical direction (Z direction). In other words, the power pad 240P may be located above or on the first region A1, and the signal pad 230bP may be located above or on the second region A2.

For example, the vertical level of the signal pad 230bP and the vertical level of the power pad 240P may be the same. The signal pad 230bP and the power pad 240P may be located on the same layer of the upper redistribution structure 200b. For example, the signal pad 230bP and the power pad 240P may be located on the second upper redistribution layer RDL2 above or on the first upper redistribution layer RDL1.

According to some embodiments, the separation distance between the signal pad 230bP and the top surface of the upper insulation layer 210 may be less than the separation distance between the grounding plane 220 and the top surface of the upper insulation layer 210. The separation distance between the power pad 240P and the top surface of the upper insulation layer 210 may be less than the separation distance between the grounding plane 220 and the top surface of the upper insulation layer 210.

According to some embodiments, the separation distance between the signal pad 230bP and the top surface of the upper insulation layer 210 may be substantially identical to the separation distance between the power pad 240P and the top surface of the upper insulation layer 210.

According to some embodiments, the extending depth of a first groove 220b_R may be greater than the extending depth of a second groove 230b_R, and the extending depth of the first groove 220b_R may be greater than the extending depth of a third groove 240b_R. According to some embodiments, the extending depth of the second groove 230b_R and the extending depth of the third groove 240b_R may be the same.

According to some embodiments, the height of a first connection terminal CT22b may be greater than the height of a second connection terminal CT23b. The height of the first connection terminal CT22b may be greater than the height of a third connection terminal CT24b. According to some embodiments, the height of the second connection terminal CT23b and the height of the third connection terminal CT24b may be the same.

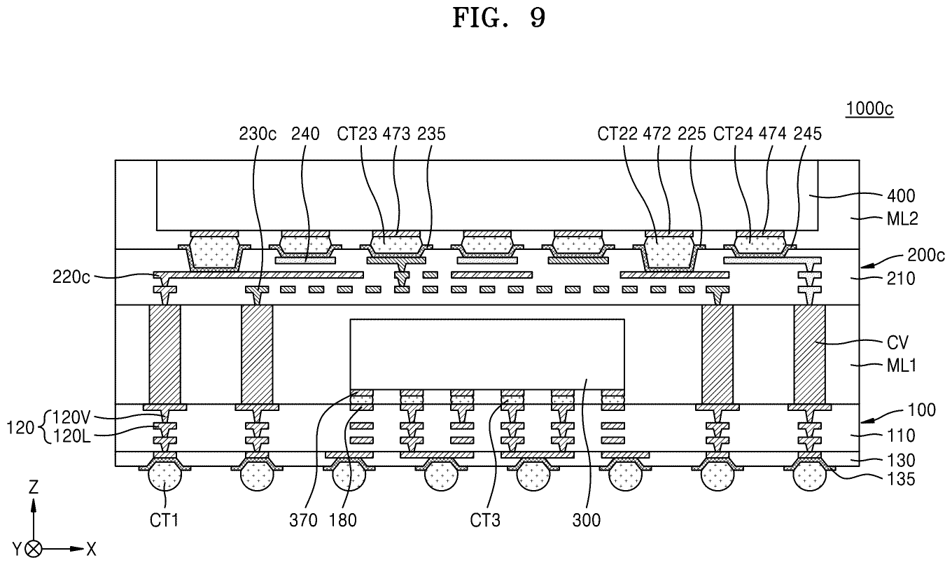

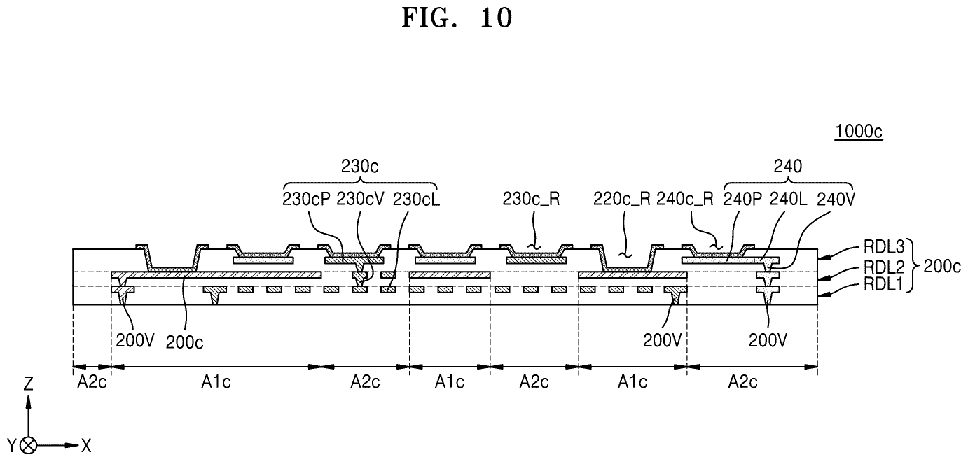

FIG. 9 is a schematic cross-sectional view of a semiconductor package 1000c according to some embodiments. FIG. 10 is an enlarged view of a portion of the semiconductor package 1000c of FIG. 9.

Most of the components constituting a semiconductor package 1000c described below and materials constituting the components thereof are substantially the same as or similar to those described with reference to FIG. 6 above. Therefore, for convenience of explanation, descriptions below focus on the differences between the semiconductor package 1000c of FIG. 9 and the semiconductor package 1000b of FIG. 6 described above.

An upper redistribution structure 200c of the semiconductor package 1000c may include a signal redistribution pattern 230c, the power redistribution pattern 240, a grounding plane 220c, and the upper insulation layer 210.

The upper redistribution structure 200c may include the first upper redistribution layer RDL1, the second upper redistribution layer RDL2, and the third upper redistribution layer RDL3.

The first upper redistribution layer RDL1 may be in direct contact with the first molding layer ML1 and the via electrode CV, the second upper redistribution layer RDL2 may be located on the first upper redistribution layer RDL1, and the third upper redistribution layer RDL3 may be located on the second upper redistribution layer RDL2.

The second upper redistribution layer RDL2 where the grounding plane 220 is located may be divided into a first region A1c and a second region A2c. The first region A1c is a region where the grounding plane 220 is located, and the second region A2c may be the remaining region. The upper insulation layer 210 and the signal via pattern 230bV may be located in the second region A2c of the second upper redistribution layer RDL2.

A signal pad 230cP may be located above or on the second region A2c. For example, the grounding plane 220c may not be located below the signal pad 230cP. In other words, the upper insulation layer 210, a signal line pattern 230cL, and the signal via pattern 230bV may be located below the signal pad 230cP.

According to some embodiments, the vertical level of the signal line pattern 230L may be lower than the vertical level of the grounding plane 220c. The vertical level of the signal pad 230cP may be higher than the vertical level of the grounding plane 220c.

For example, the signal line pattern 230cL may be located on the first upper redistribution layer RDL1, the grounding plane 220c may be located on the second upper redistribution layer RDL2, and the signal pad 230cP and the power pad 240P may be located on the third upper redistribution layer RDL3.

According to some embodiments, the extending depth of a first groove 220c_R may be greater than the extending depth of a second groove 230c_R, and the extending depth of the first groove 220c_R may be greater than the extending depth of a third groove 240c_R. According to some embodiments, the extending depth of the second groove 230c_R and the extending depth of the third groove 240c_R may be the same.

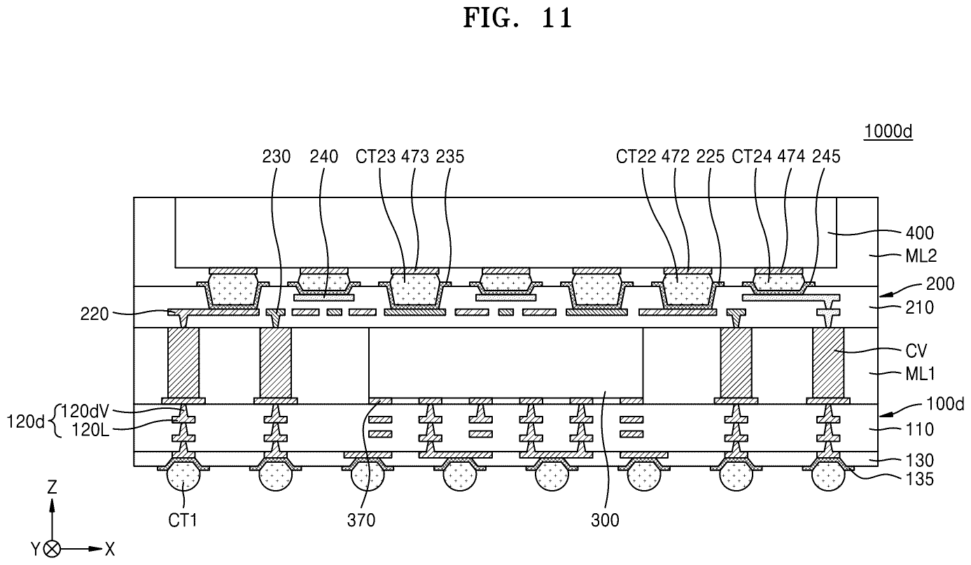

FIG. 11 is a schematic cross-sectional view of a semiconductor package 1000d according to some embodiments.

Most of the components constituting a semiconductor package 1000d described below and materials constituting the components thereof are substantially the same as or similar to those described with reference to FIG. 1 above. Therefore, for convenience of explanation, descriptions below focus on the differences between the semiconductor package 1000d of FIG. 10 and the semiconductor package 1000 of FIG. 1 described above.

The input/output pad 370 of the lower semiconductor chip 300 of the semiconductor package 1000d may directly contact and be electrically connected to a lower redistribution structure 100d. For example, the lower redistribution structure 100d may be formed on the bottom surface of the lower semiconductor chip 300 through a chip-first process.

According to some embodiments, a lower via pattern 120dV of the lower redistribution structure 100d may have a tapered shape in which the horizontal width of the lower via pattern 120dV increases as the distance from the lower semiconductor chip 300 increases. The first molding layer ML1 of the semiconductor package 1000d may be located on the lower redistribution structure 100d and may at least partially surround the lower semiconductor chip 300. The top surface of the first molding layer ML1 may be coplanar with the top surface of the lower semiconductor chip 300.

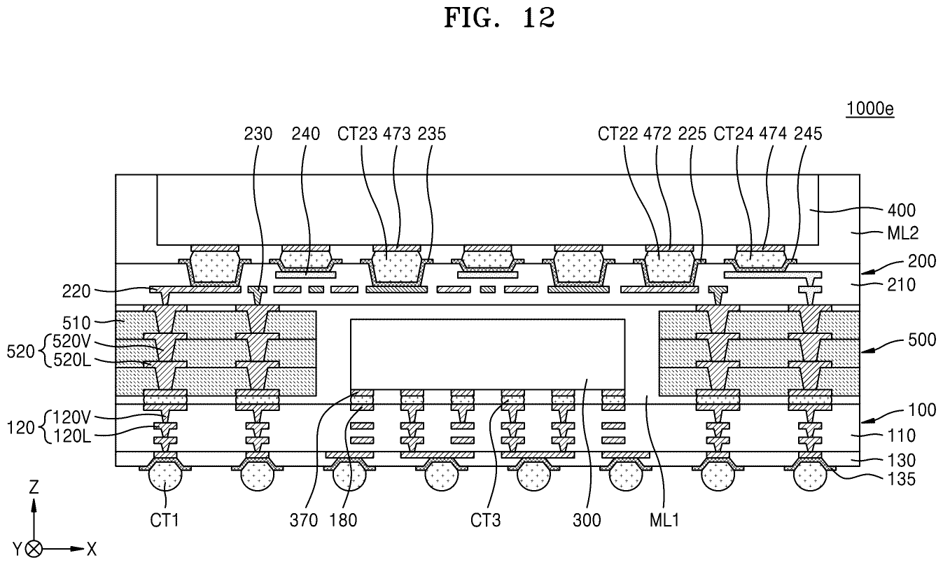

FIG. 12 is a schematic cross-sectional view of a semiconductor package 1000e according to some embodiments.

Most of the components constituting a semiconductor package 1000e described below and materials constituting the components thereof are substantially the same as or similar to those described with reference to FIG. 1 above. Therefore, for convenience of explanation, descriptions below focus on the differences between the semiconductor package 1000e of FIG. 12 and the semiconductor package 1000 of FIG. 1 described above.

The semiconductor package 1000e may further include a connection structure 500.

The connection structure 500 of the semiconductor package 1000e may be disposed on the lower redistribution structure 100. For example, the connection structure 500 may be electrically connected to a portion of the lower redistribution pattern 120 of the lower redistribution structure 100. The connection structure 500 may electrically connect the upper redistribution structure 200 to the lower redistribution structure 100.

The connection structure 500 may include a cavity extending from the top surface of the connection structure 500 to the bottom surface of the connection structure 500. The lower semiconductor chip 300 may be mounted inside or in the cavity of the connection structure 500. In other words, the lower semiconductor chip 300 may be mounted within the cavity of the connection structure 500 and may be disposed to be spaced apart from the inner wall of the cavity of the connection structure 500. The first molding layer ML1 may be located between the connection structure 500 and the lower semiconductor chip 300.

The cavity may be formed in the center of the connection structure 500, as shown in FIG. 12, but the number and arrangement of cavities are not limited to those shown in the drawing.

The connection structure 500 may include a plurality of base layers 510 and a via structure 520. According to some embodiments, the plurality of base layers 510 may include first to third base layers stacked in the vertical direction (Z direction). For example, the connection structure 500 may have a multi-layered structure including the first to third base layers. The plurality of base layers 510 may surround at least a portion of the via structure 520.

According to embodiments, the plurality of base layers 510 may each include thermosetting resin such as phenol resin and epoxy resin, thermoplastic resin such as a polyimide, or an insulation material formed by impregnating at least one resin selected from among the above-stated resins in a core material including an inorganic filler and/or glass fiber.

For example, the plurality of base layers 510 may each include prepreg, ABF, FR-4, tetrafunctional epoxy, polyphenylene ether, BT, epoxy/polyphenylene oxide, Thermount, cyanate ester, polyimide, liquid crystal polymer, or a combination thereof.

The via structure 520 may include a plurality of connection pads 520L and a plurality of connection vias 520V. The plurality of connection pads 520L may extend in the horizontal direction on the top surfaces or the bottom surfaces of the plurality of base layers 510, respectively.

According to some embodiments, the plurality of connection pads 520L may include first to fourth connection pads located at different vertical levels. First connection pads, which are the lowermost connection pads from among the plurality of connection pads 520L, may be connected to the lower redistribution structure 100, and fourth connection pads, which are the uppermost connection pads from among the plurality of connection pads 520L, may be connected to the upper redistribution structure 200.

The plurality of connection vias 520V may extend in the vertical direction within the plurality of base layers 510. A plurality of connection vias 520V may connect the plurality of connection pads 520L located at different vertical levels to one another. According to some embodiments, the plurality of connection vias 520V may include first to third connection vias located at different vertical levels.

According to embodiments, the plurality of connection pads 520L may include electrolytically deposited (ED) copper foil, rolled-annealed (RA) copper foil, stainless steel foil, aluminum foil, ultra-thin copper foil, sputtered copper, or a copper alloy. According to embodiments, the plurality of connection vias 520V may each include copper, nickel, stainless steel, beryllium copper, or a combination thereof.

While the present disclosure has been particularly shown and described with reference to embodiments thereof, it will be understood that various changes in form and details may be made therein without departing from the spirit and scope of the following claims.

What is claimed is:

1. A semiconductor package comprising:
a lower redistribution structure;
a lower semiconductor chip on the lower redistribution structure; and
an upper redistribution structure on the lower semiconductor chip and comprising a signal pad, a power pad, a grounding plane, and an upper insulation layer,
wherein the signal pad, the power pad, and the grounding plane are in the upper insulation layer,
wherein a distance between the signal pad and the lower redistribution structure in a vertical direction is less than a distance between the power pad and the lower redistribution structure in the vertical direction, and
wherein the vertical direction is perpendicular to an upper surface of the lower redistribution structure.

2. The semiconductor package of claim 1, wherein the distance between the signal pad and the lower redistribution structure in the vertical direction is identical to a distance between the grounding plane and the lower redistribution structure in the vertical direction.

3. The semiconductor package of claim 2, wherein:
the upper redistribution structure further comprises a signal line pattern electrically connected to the signal pad,
a distance between the signal line pattern and the lower redistribution structure in the vertical direction is identical to the distance between the signal pad and the lower redistribution structure in the vertical direction, and
a width of the signal pad in a horizontal direction is from about 10 times to about 30 times greater than a width of the signal line pattern in the horizontal direction, the horizontal direction intersecting the vertical direction.

4. The semiconductor package of claim 2, wherein:
a distance between the signal pad and a bottom surface of the upper insulation layer in the vertical direction by about 10 μm to about 50 μm, and
a distance between the power pad and a top surface of the upper insulation layer in the vertical direction by about 10 μm to about 50 μm.

5. The semiconductor package of claim 1, further comprising:
a molding layer on the lower redistribution structure and at least partially surrounding the lower semiconductor chip; and
a via electrode extending into the molding layer and electrically connecting the lower redistribution structure to the upper redistribution structure,
wherein the upper redistribution structure comprises a first upper redistribution layer contacting the molding layer and the via electrode and a second upper redistribution layer on the first upper redistribution layer,
the first upper redistribution layer comprises the signal pad and the grounding plane, and
the second upper redistribution layer comprises the power pad.

6. The semiconductor package of claim 1, further comprising:
a molding layer on the lower redistribution structure and at least partially surrounding the lower semiconductor chip; and
a via electrode extending into the molding layer and electrically connecting the lower redistribution structure to the upper redistribution structure,
wherein the upper redistribution structure comprises a first upper redistribution layer that contacts the molding layer and the via electrode, a second upper redistribution layer on the first upper redistribution layer, and a third upper redistribution layer on the second upper redistribution layer,
the first upper redistribution layer comprises the signal pad,
the second upper redistribution layer comprises the grounding plane, and
the third upper redistribution layer comprises the power pad.

7. The semiconductor package of claim 1, wherein:
the upper redistribution structure comprises a first groove, a second groove, and a third groove,
the first groove extends from a top surface of the upper insulation layer toward the grounding plane,
the second groove extends from the top surface of the upper insulation layer toward the signal pad, and
the third groove extends from the top surface of the upper insulation layer toward the power pad.

8. The semiconductor package of claim 7, wherein a depth of the third groove in the vertical direction is less than a depth of the first groove and a depth of the second groove in the vertical direction.

9. The semiconductor package of claim 7, wherein a depth of the first groove in the vertical direction is identical to a depth of the second groove in the vertical direction.

10. The semiconductor package of claim 1, further comprising:
an upper semiconductor chip on the upper redistribution structure; and
a plurality of connection terminals between the upper semiconductor chip and the upper redistribution structure.

11. The semiconductor package of claim 10, wherein:
the plurality of connection terminals comprise a first connection terminal, a second connection terminal, and a third connection terminal,
the first connection terminal extends into an upper portion of the upper insulation layer and is electrically connected to the grounding plane,
the second connection terminal extends into the upper portion of the upper insulation layer and is electrically connected to the signal pad,
the third connection terminal extends into the upper portion of the upper insulation layer and is electrically connected to the power pad, and
a height of the third connection terminal in the vertical direction is less than a height of the first connection terminal in the vertical direction.

12. The semiconductor package of claim 11, wherein the height of the third connection terminal in the vertical direction is identical to a height of the second connection terminal in the vertical direction.

13. A semiconductor package comprising:
a lower redistribution structure;
a lower semiconductor chip on the lower redistribution structure; and
an upper redistribution structure on the lower semiconductor chip and comprising a signal redistribution pattern, a power pad, a grounding plane, and an upper insulation layer,
wherein the upper redistribution structure comprises a plurality of redistribution layers,
wherein a first upper redistribution layer of the plurality of redistribution layers comprises a first region and a second region,
wherein the grounding plane is in the first region, and
wherein a signal pad of the signal redistribution pattern is on the second region.

14. The semiconductor package of claim 13, wherein:
the signal redistribution pattern comprises a signal line pattern,
a distance between the signal pad and the lower redistribution structure in a vertical direction is greater than a distance between the signal line pattern and the lower redistribution structure in the vertical direction,
the vertical direction is perpendicular to an upper surface of the lower redistribution structure, and
the signal redistribution pattern comprises a signal via pattern electrically connecting the signal pad to the signal line pattern.

15. The semiconductor package of claim 14, wherein the distance between the signal line pattern and the lower redistribution structure in the vertical direction is less than or equal to a distance between the grounding plane and the lower redistribution structure in the vertical direction.

16. The semiconductor package of claim 14, wherein:
a bottom surface of the signal pad is electrically connected to the signal via pattern, and
the signal pad at least partially overlaps the signal line pattern in the vertical direction.

17. The semiconductor package of claim 13, wherein the signal pad and the power pad are on a second upper redistribution layer of the plurality of redistribution layers, and wherein the second upper redistribution layer is on the first upper redistribution layer.

18. A semiconductor package comprising:
a lower redistribution structure;
a lower semiconductor chip on the lower redistribution structure;
a molding layer on the lower redistribution structure and at least partially surrounding the lower semiconductor chip;
an upper redistribution structure on the molding layer and comprising a signal pad, a power pad, a grounding plane, and an upper insulation layer;
a via electrode extending into the molding layer and electrically connecting the lower redistribution structure to the upper redistribution structure; and
an upper semiconductor chip on the upper redistribution structure,
wherein the signal pad, the power pad, and the grounding plane are in the upper insulation layer,
wherein a distance between the signal pad and the lower redistribution structure in a vertical direction is identical to a distance between the grounding plane and the lower redistribution structure in the vertical direction, and
wherein the vertical direction is perpendicular to an upper surface of the lower redistribution structure.

19. The semiconductor package of claim 18, wherein the upper insulation layer is between the signal pad and the power pad.

20. The semiconductor package of claim 18, wherein:
the upper redistribution structure further comprises a signal line pattern that is electrically connected to the signal pad,
a distance between the signal line pattern and the lower redistribution structure in the vertical direction is identical to the distance between the signal pad and the lower redistribution structure in the vertical direction, and
the grounding plane is spaced apart from the signal line pattern and the signal pad in a horizontal direction that intersects the vertical direction.
